(19) United States
(12) Patent Application Publication
(10) Pub. No.: US 2025/0140588 A1
(43) Pub. Date: May 1, 2025

(54) DIE BONDING APPARATUS AND DIE BONDING METHOD USING THE SAME

(71) Applicant: SAMSUNG ELECTRONICS CO., LTD., SUWON-SI (KR)

(72) Inventors: Ilyoung HAN, Suwon-si (KR); Sumin KIM, Suwon-si (KR); Minwoo RHEE, Suwon-si (KR); Hyunjin LEE, Suwon-si (KR); Kyeongbin LIM, Suwon-si (KR)

(21) Appl. No.: 18/790,371

(22) Filed: Jul. 31, 2024

(30) Foreign Application Priority Data
Oct. 30, 2023 (KR) 10-2023-0146826

(51) Int. Cl. H01L 21/677; H01L 21/67; H01L 21/68

(52) U.S. Cl. CPC H01L 21/67709; H01L 21/6715; H01L 21/67766; H01L 21/68; H01L 2221/68309

(57) ABSTRACT

A wafer on which a hydrophilic pattern is applied is provided to a die seat on which a first magnetic pattern is formed and a hydrophobic pattern is applied around the hydrophilic pattern. Liquid is dispensed to the die seat. A first die on which a second magnetic pattern is formed is seated on the wafer and the first die is first-aligned using capillary force of the liquid. Liquid is dispensed onto an upper surface of the first die. A second die is seated on the upper surface of the first die and the second die is first-aligned with capillary force of the liquid on the upper surface of the first die. A magnetic field is generated in the first magnetic pattern and the second magnetic pattern and the first magnetic pattern and the second magnetic pattern are secondly-aligned using magnetic force.

### CROSS-REFERENCE TO RELATED APPLICATION(S)

This application claims priority under 35 U.S.C. § 119 to Korean Patent Application No. 10-2023-0146826 filed on Oct. 30, 2023 in the Korean Intellectual Property Office, the disclosure of which is herein incorporated by reference in its entirety.

### TECHNICAL FIELD

The present disclosure relates to die bonding and, more specifically, to a die bonding apparatus and a die bonding method using the same.

### DISCUSSION OF THE RELATED ART

Semiconductor devices are generally packaged, after being fabricated, so as to provide protection to the semiconductor device and to simplify its incorporation into various electronic devices. Modern semiconductor device packaging techniques may be able to incorporate multiple semiconductor devices into fewer packages so as to save space, save power, and increase performance. One approach that has been used is to stack multiple semiconductor devices upon one another. These techniques have come to be known as 3D packaging.

Die-to-wafer and die-to-die bonding technologies have come to prominence as next-generation packaging technologies to realize high-density interconnections in the field of 3D packaging.

In placing these increasingly smaller semiconductor dies into the stack, proper die alignment becomes an important but potentially challenging task. Current die alignment technology is based on optical vision, and visible light range lighting and general cameras are used for die alignment. However, using these vision-based approaches to die alignment may result in alignment errors, particularly as the stack of dies gets taller as the growing height of the stack requires that the camera system be able to focus on dies at different focal lengths.

Die alignment technology using optical vision might not be suitable for a die having a circuit line width pitch that is equal to or smaller than about 1 μm, and in such cases, alignment may be slow and prone to error.

### SUMMARY

A die bonding apparatus includes a wafer shelf supplying a wafer on which a hydrophilic pattern is applied to a die seating portion on which a first magnetic pattern is formed and a hydrophobic pattern is applied around the hydrophilic pattern. A die shelf supplies a die on which a second magnetic pattern connected to the first magnetic pattern of the die seating portion is formed. A die transfer actuator moves and seats a first die from the die shelf onto the wafer or a second die onto the first die disposed on the wafer. A liquid dispenser supplies liquid to the die seating portion of the wafer or an upper surface of the first die to first align the first die on the wafer or the second die on the first die by capillary force. A magnet device generates a magnetic field causing second alignment between the first magnetic pattern and the second magnetic pattern by magnetic force.

A die bonding method using a die bonding device comprising a wafer shelf, a liquid dispenser, a die conveyer and a magnet device, includes: supplying a wafer, on which a hydrophilic pattern is formed, to a die seating portion, on which a first magnetic pattern is formed and a hydrophobic pattern is applied around the hydrophilic pattern, by means of the wafer shelf; dispensing liquid to the die seating portion, by means of the liquid dispenser; seating a first die, on which a second magnetic pattern connected to the first magnetic pattern is formed, on the wafer and first aligning the first die using capillary force of the liquid, by means of the die conveyor; dispensing liquid onto an upper surface of the first die, by means of the liquid dispenser; seating a second die on the upper surface of the first die and first aligning the second die with capillary force of the liquid on the upper surface of the first die, by means of the die conveyor; and generating a magnetic field in the first magnetic pattern and the second magnetic pattern and secondly aligning the first magnetic pattern and the second magnetic pattern using magnetic force, by means of the magnet device.

A die bonding method includes providing a wafer on which a hydrophilic pattern is applied to a die seating portion on which a first magnetic pattern is formed and a hydrophobic pattern is applied around the hydrophilic pattern. Liquid is dispensed to the die seating portion. A first die on which a second magnetic pattern connected to the first magnetic pattern is formed is seated on the wafer and the first die is first-aligned using capillary force of the liquid. Liquid is dispensed onto an upper surface of the first die. A second die is seated on the upper surface of the first die and the second die is first-aligned with capillary force of the liquid on the upper surface of the first die. A magnetic field is generated in the first magnetic pattern and the second magnetic pattern and the first magnetic pattern and the second magnetic pattern are secondly-aligned using magnetic force.

A die bonding method includes providing a wafer on which a hydrophilic pattern is applied to a die seating portion on which a first magnetic pattern is formed and a hydrophobic pattern is applied around the hydrophilic pattern. Liquid is dispensed to the die seating portion. A first die on which a second magnetic pattern connected to the first magnetic pattern is formed is seated on the wafer and the first die is first-aligned using capillary force of the liquid. A magnetic field is generated in the first magnetic pattern and the second magnetic pattern and the first magnetic pattern and the second magnetic pattern are secondly-aligned with magnetic force. Liquid is dispensed onto an upper surface of the first die. A second die is seated on the upper surface of the first die and the second die is first-aligned with capillary force of the liquid on the upper surface of the first die. A magnetic field is generated in the first die and the second die and the first die and the second die are secondly-aligned using magnetic force.

### BRIEF DESCRIPTION OF DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a schematic perspective view of a die bonding apparatus according to an embodiment of the present inventive concept;

FIG. 2 is a schematic diagram illustrating a hydrophilic pattern and a hydrophobic pattern on a wafer of the die bonding apparatus of FIG. 1;

FIG. 3 is a cross-sectional view in a direction of A-A′ in FIG. 2;

FIG. 4 is a schematic cross-sectional view of a magnetic field providing chamber of a die bonding apparatus according to an embodiment of the present inventive concept;

FIG. 5 is a schematic cross-sectional view of a magnet device of a die bonding apparatus according to an embodiment of the present inventive concept;

FIG. 6 is a schematic cross-sectional view of a bonding pressurizing device of a die bonding apparatus according to an embodiment of the present inventive concept;

FIG. 7 is a flowchart of a die bonding method according to an embodiment of the present inventive concept;

FIGS. 8A to 8G are schematic diagrams illustrating the die bonding method of FIG. 7;

FIG. 9 is a flowchart of a die bonding method according to an embodiment of the present inventive concept; and

FIGS. 10A to 10D are schematic diagrams illustrating the die bonding method of FIG. 9.

### DETAILED DESCRIPTION

Hereinafter, embodiments in the present inventive concept will be described in detail with reference to the accompanying drawings.

The embodiments of the present inventive concept may be modified into other forms and are provided so that this disclosure will be thorough and complete and will fully convey the scope of the invention to those of ordinary skill in the art. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. Like reference numerals may denote like elements throughout the specification and the drawings.

In the present inventive concept, the meaning of a “connection” of a component to another component includes an indirect connection through another element as well as a direct connection between two components. In addition, in some cases, the meaning of “connection” includes all “electrical connections”.

It may be understood that when an element is referred to with “first” and “second,” the element is not necessarily limited thereby. They may be used for distinguishing the element from the other elements, and might not limit the sequence or importance of the elements. In some cases, a first element may be referred to as a second element without departing from the scope of the claims set forth herein. Similarly, a second element may also be referred to as a first element.

A singular term may include a plural form unless otherwise indicated.

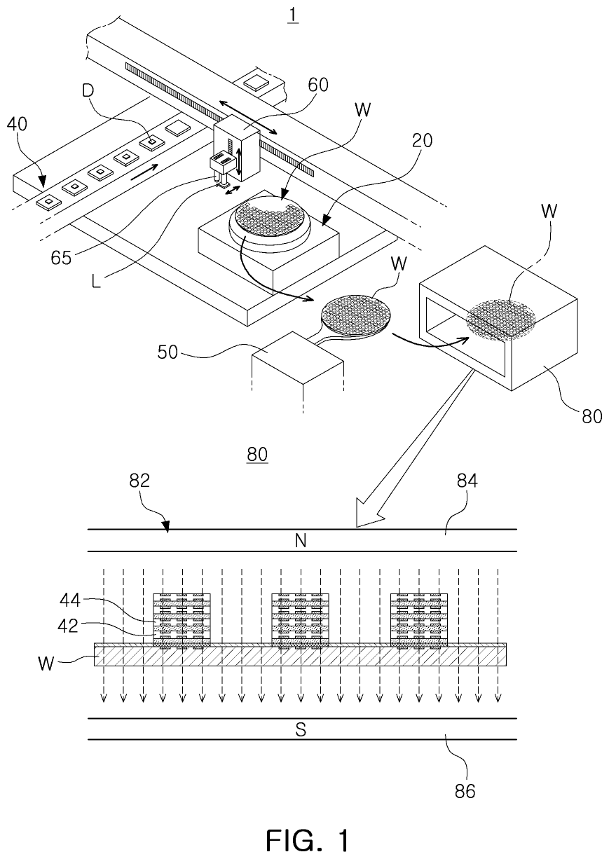

FIG. 1 is a schematic perspective view of a die bonding apparatus according to an embodiment of the present inventive concept.

Referring to FIG. 1, a die bonding apparatus, 1 according to an embodiment of the present inventive concept, includes a wafer shelf 20, a die conveyor 40, a die transfer actuator 60, a liquid dispenser 65, and a magnet device 80.

The die bonding apparatus 1 is an apparatus for disposing a die D on a wafer W used in a wafer package process and aligning the wafer W and die D. In addition, in order to stack the dies D in multiple layers to implement high-density interconnection, the die bonding apparatus 1 disposes one die D on another die D and aligns the dies D. Bonding between the wafer W and die D may be referred to as wafer-to-die bonding, and bonding between the die D and the die D may be referred to as die-to-die bonding.

The wafer shelf 20 provides the wafer W, and the die conveyor 40 supplies the die D attached to the wafer W. The wafer shelf 20 is shown in the form of a rotatable shelf in FIG. 1 but is not necessarily limited thereto.

In addition, in FIG. 1, the die conveyor 40 is shown in the form of a conveyor belt, but is not necessarily limited thereto. For example, a semiconductor waffle pack for supplying the die D may also be used as the die conveyor 40.

The die transfer actuator 60 is not necessarily limited to a particular shape as long as it may pick up the die D from the die conveyor 40, move the die D above the wafer W, and dispose the die D down.

The liquid dispenser 65 discharges liquid, for example, water or functional liquid, to be dropped on the wafer W, thereby allowing the wafer W and the die D or the die D and the die D to be aligned by capillary force. In the present inventive concept, alignment by capillary force of a liquid L is referred to as a first alignment, and since alignment at the micron (μm) level may be made, which may be referred to as coarse alignment.

In the present inventive concept, the die D combined with the wafer W is referred to as a first die 42 and the die stacked on the die D is referred to as a second die 44. Depending on the design, more layers of dies may be stacked on the second die 44.

The liquid dispenser 65 of the present embodiment is shown as being combined with and integrated with the die transfer actuator 60, but liquid may be dispensed through a liquid dispenser 65 separate from the die transfer actuator 60.

The magnet device 80 is a device generating a magnetic field within its environment. In the embodiment of FIG. 1, the magnet device 80 supplies a magnetic field generating magnetic force to a magnetic pattern disposed in advance on the wafer W and the die D to enable ultra-fine alignment. When alignment is performed using a magnetic field, nanometer-level alignment may be performed, which may be referred to as fine alignment.

As an example, the magnet device 80 may be a magnetic field generating chamber 82. Permanent or electromagnets 84 and 86 having different polarities may be disposed in upper and lower portions of the magnetic field generating chamber 82 to supply a magnetic field to the wafer W and the first die 42 or the first die 42 and the second die 44, being first aligned, in a direction, substantially perpendicular to a floor upon which the die bonding apparatus is installed.

The first aligned wafer W of wafer-to-die and die-to-die bonding in the wafer shelf 20 may be transferred by the wafer transfer tool 50 and accommodated in the magnetic field generating chamber 82.

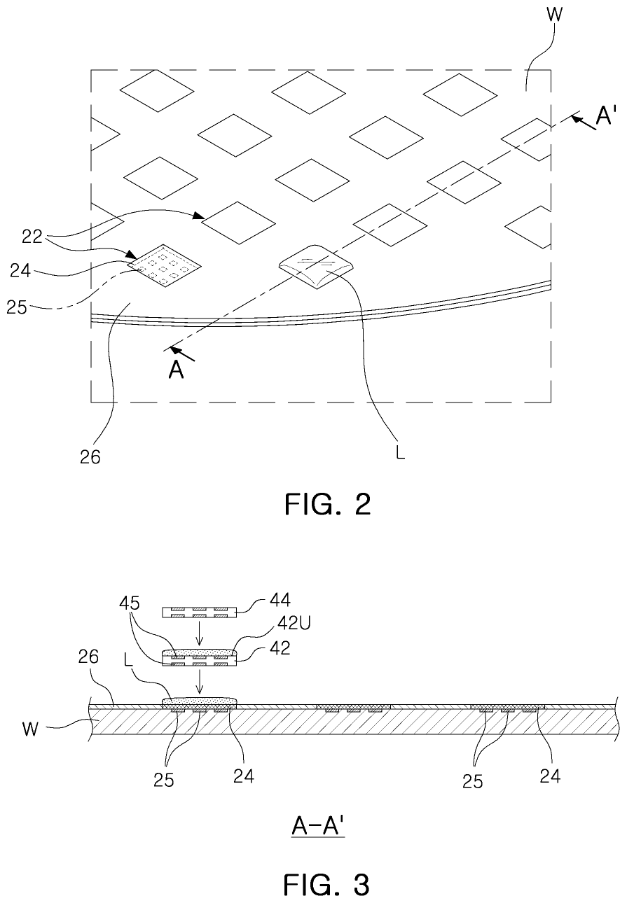

FIG. 2 is a schematic diagram illustrating a hydrophilic pattern and a hydrophobic pattern on a wafer of the die bonding apparatus of FIG. 1, and FIG. 3 is a cross-sectional view in a direction of A-A′ of FIG. 2. FIG. 3 illustrates the first die 42 and the second die 44 being stacked.

Referring to FIGS. 2 and 3, to perform wafer-to-die and die-to-die bonding in the die bonding apparatus 1 of the present inventive concept, the wafer W and die D are preprocessed. The wafer W provided to the wafer shelf 20 is formed with a die seating portion 22 on which the first die 42 is seated. A hydrophilic pattern 24 is applied to the die seating portion 22 to match the shape of the die, and a hydrophobic pattern 26 is applied around the die seating portion 22.

A first magnetic pattern 25 is disposed on the die seating portion 22 of the wafer W, and the hydrophilic pattern 24 is applied an upper portion of the first magnetic pattern 25. The hydrophobic pattern 26 is applied around the hydrophilic pattern 24 so that the first die 42 is stacked on the hydrophilic pattern 24.

The liquid L from the liquid dispenser is dispensed in the hydrophilic pattern 24 of the wafer W. The liquid dispenser 65 controls a precise discharge amount and position of the liquid L, and thus, the precise liquid dispenser 65 may be used.

The liquid L used in the die bonding apparatus 1 of the present inventive concept may be water generating capillary force or may be a functional liquid removing a natural oxide film present on a wiring pad and magnetic pattern of the die D or reacting with a dielectric surface to form a silanol group (Si—OH).

The first die 42 is stacked on the liquid L on the hydrophilic pattern 24. Here, the first die 42 is formed with a second magnetic pattern 45 connected to the first magnetic pattern 25 in the die seating portion 22 of the wafer W. The die transfer actuator 60 stacks the first die 42 on the wafer W from the die conveyor 40 of the die transfer device 1. Here, when the first die 42 is stacked on the wafer W, coarse alignment, for example, first alignment, is induced by the capillary force of the liquid L.

In addition, the liquid dispenser 65 supplies the liquid L to an upper surface 42U of the first die 42 again, and when the second die 44 is stacked on the first die 42, coarse alignment, for example, first alignment, is induced by capillary force of the liquid L. In die-to-die bonding, a hydrophilic pattern may also be formed on the upper surface 42U of the first die 42, and due to the same shape of the first die 42 and the second die 44, the first alignment is performed by the shape of the die. Here, the first alignment of wafer-to-die and die-to-die has a precision ranging from hundreds of nm to several μm.

A fine alignment of wafer-to-die, die-to-die, for example, a second alignment, is induced by attraction of a magnetic material patterned by applying a magnetic field between the first magnetic pattern 45 and the second magnetic pattern 45 using an electromagnet or a permanent magnet while maintaining the first aligned precision. Here, the second alignment of wafer-to-die and die-to-die has a precision of several tens of nanometers (nm). The strength of the magnetic field may have a large value by which a magnetic material of the magnetic pattern within the die may reach a magnetic saturation value.

The magnetic material used in the first magnetic pattern 25 and the second magnetic pattern 45 is configured to easily change a direction of its spin by a magnetic field and exhibits strong magnetic force even when thin and small in volume, and thus, the magnetic material has a high permeability and saturation magnetization value. Therefore, among magnetic materials, soft magnetic materials having low coercivity and high saturation magnetization value may be suitable. The soft magnetic materials may include Fe65-70Co30-35, permalloy (Ni60-80Fe40-20), soft-ferrite, and/or FePSi.

Soft magnetic materials may be deposited by electroplating, sputtering, e-beam deposition, thermal evaporation, etc., so they are suitable for patterning through deposition or etching. In addition, since these magnetic materials tend to lose their ferromagnetic properties depending on a composition of an alloy and a change in phase, they may be oxidation resistant and stable materials that do not undergo phase transformation depending on a heat treatment temperature during a process.

The magnet device 80 providing magnetic force for inducing the second alignment is implemented in the following embodiment.

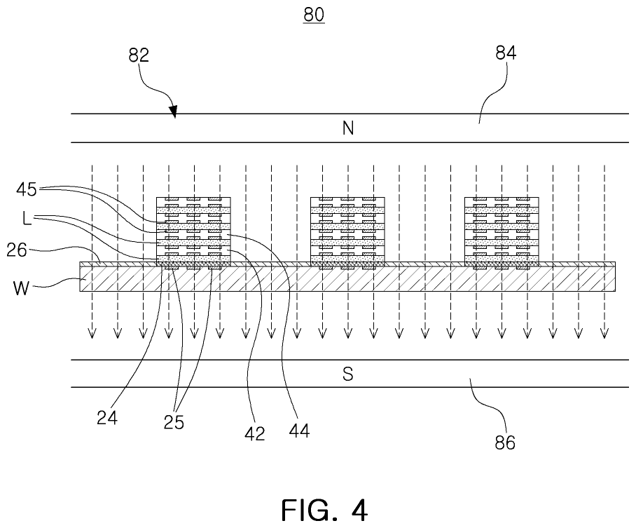

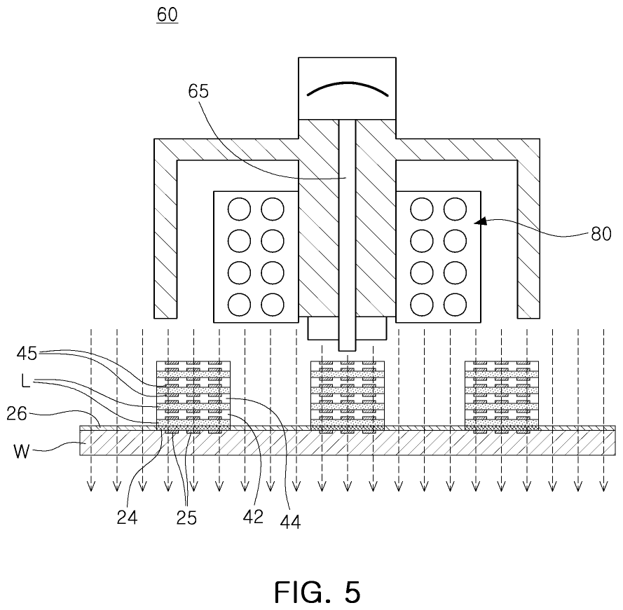

FIG. 4 is a schematic cross-sectional view of a magnetic field providing chamber of a die bonding apparatus according to an embodiment of the present inventive concept, and FIG. 5 is a magnet device of a die bonding apparatus according to an embodiment of the present inventive concept.

The magnet device 80 is a device generating a magnetic field. In the embodiment of FIG. 4, as described above with reference to FIG. 1, the magnet 80 may be the magnetic field generating chamber 82 to which the first aligned wafer is transferred to be accommodated, after the first alignment is induced by capillary force by the liquid L from the wafer shelf 20 for wafer-to-die and die-to-die bonding.

The magnets 84 and 86 having different polarities are disposed in the upper and lower portions of the magnetic field generating chamber 82 to supply magnetic field in a direction, substantially perpendicular to a floor upon which the die bonding apparatus is installed, to the first aligned wafer W and the first die 42 or the first die 42 and the second die 44.

In the present embodiment, although only one magnetic field generating chamber 82 is shown, multiple magnetic field generating chambers may be configured to simultaneously perform the second alignment of wafer-to-die and die-to-die, to perform an operation at a faster speed.

The magnet device 80 of the embodiment of FIG. 5 generates magnetic force with an electromagnet and may be combined and integrated with the die transfer actuator 60. In addition, the liquid dispenser 65 for generating capillary force may also be combined with the die transfer actuator 60 to form one module.

In the embodiment of FIG. 5, after first aligning the first die 42 on the wafer W, a magnetic field may be applied to perform second alignment first. After dispensing the liquid L on the upper surface 42U of the first die 42 on the secondly aligned wafer W, the second die 44 may be mounted, and then, a magnetic field for second alignment may be applied again to perform die-to-die bonding. In addition, after first aligning the first die 42 on the wafer W and first aligning the second die 44 on the first die 42, a magnetic field may be applied, and after a plurality of dies are mounted and first aligned, a magnetic field may be applied.

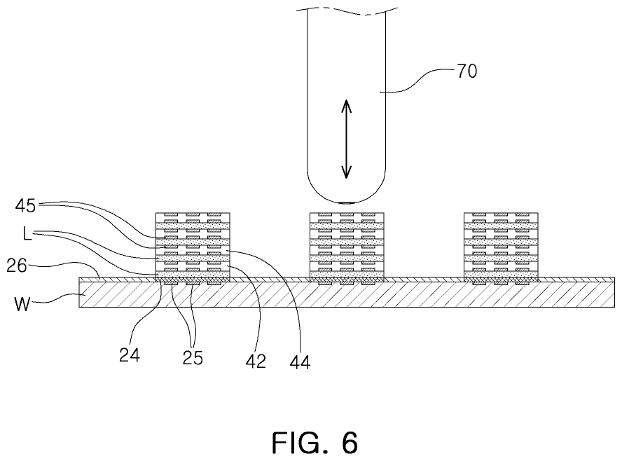

FIG. 6 is a schematic cross-sectional view of a bonding pressurizing device of a die bonding apparatus according to an embodiment of the present inventive concept.

Referring to FIG. 6, the die bonding apparatus 1 of the present inventive concept may further include a pressurizer 70.

The pressurizer 70 may pressurize the uppermost die for the second alignment to dry liquid when applying a magnetic field for the second alignment to the wafer-to-die and die-to-die. The pressurizer 70 may be elastic rubber, and a head portion thereof may be rubber.

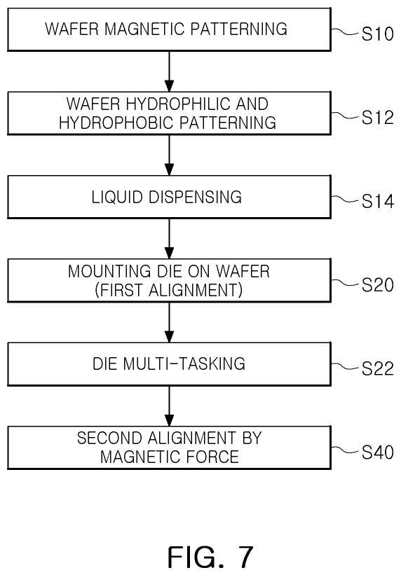

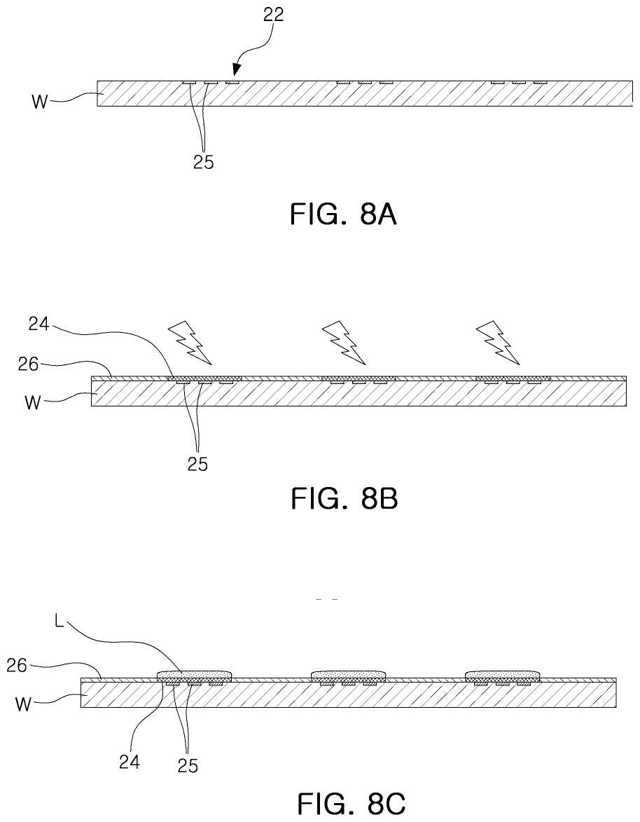

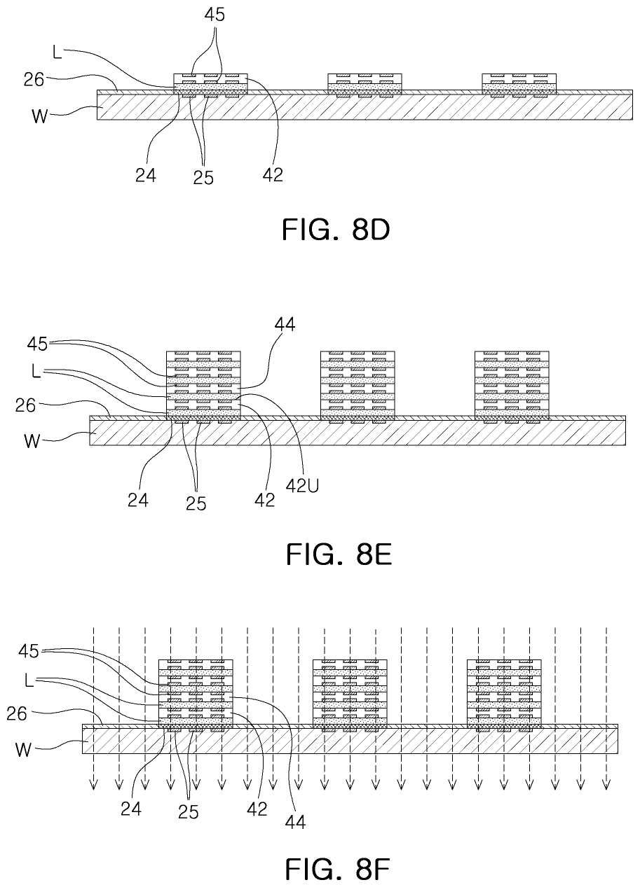

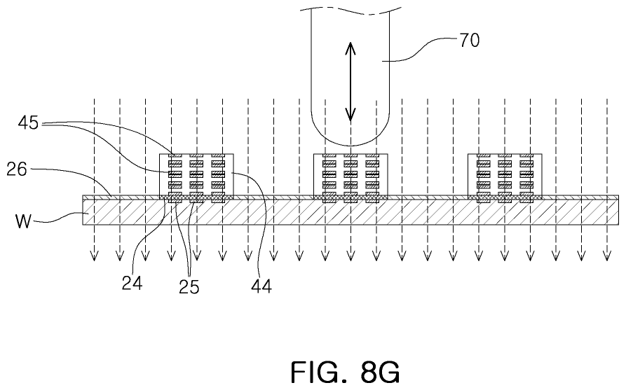

FIG. 7 is a flowchart of a die bonding method according to an embodiment of the present inventive concept, and FIGS. 8A to 8G are schematic diagrams illustrating the die bonding method of FIG. 7.

Referring to FIGS. 7 and 8, the die bonding method, according to an embodiment of the present inventive concept, may be accommodated using the die bonding apparatus described above.

First, magnetic patterning (S10, FIG. 8A) is performed on the wafer W. The first magnetic pattern 25 is formed on the die seating portion 22 of the wafer W. After forming the first magnetic pattern 25 on the wafer W, the hydrophilic pattern 24 is formed in a position in which the die D is mounted, and the hydrophobic pattern 26 is applied around the hydrophilic pattern 24 (S12, FIG. 8B).

After the wafer W is prepared, the liquid L is dispensed on the hydrophilic pattern 24 (S14, FIG. 8C). The liquid L dispensed on the wafer W may be water generating capillary force or may be a functional liquid removing a natural oxide film present on a wiring pad and magnetic pattern of the die D or reacting with a dielectric surface to form a silanol group (Si—OH).

After dispensing the liquid L, the first die 42 is mounted (S20, FIG. 8D). The second magnetic pattern 45 connected to the first magnetic pattern 25 is formed at the die seating portion 22 of the wafer W on the first die 42.

Here, the magnetic material used in the first magnetic pattern 25 and the second magnetic pattern 45 is configured to be easily change a direction of spin by a magnetic field and exhibits strong magnetic force even when thin and small in volume, and thus, the magnetic material has a high permeability and saturation magnetization value. Therefore, among magnetic materials, soft magnetic materials having low coercivity and high saturation magnetization value may be suitable. The soft magnetic materials may include Fe65-70Co30-35, permalloy (Ni60-80Fe40-20), soft-ferrite, and/or FePSi.

After the first die 42 is mounted on the wafer W, liquid is dispensed again on the upper surface 42U of the first die 42, and then the second die 44 is mounted on the upper portion of the first die 42. Since multiple dies may be stacked in this manner, this is called die multi-stacking (S22, FIG. 8E).

In this manner, water or functional liquid is dropped on the wafer W and the die D so that the wafer W and die D or die D and die D may be aligned by capillary force. In the present inventive concept, alignment by capillary force of the liquid L is referred to as the first alignment, and since alignment at the micron (μm) level may be enabled, it is referred to as coarse alignment. Here, the first alignment of wafer-to-die and die-to-die has a precision of hundreds of nm to several μm.

The first aligned wafer W described above is moved to the magnet device 80, and a magnetic field generating magnetic force is applied to the first aligned wafer W and die D to enable ultra-fine alignment (S40, FIG. 8F). The case of alignment using a magnetic field is called second alignment, and the second alignment is called fine alignment because alignment at the nanometer level is possible.

As an example of the magnet device 80, the magnet device 80 may be a magnetic field generating chamber 82. Permanent or electromagnets 84 and 86 having different polarities may be disposed in upper and lower portions of the magnetic field generating chamber 82 to supply a magnetic field to the wafer W and the first die 42 or the first die 42 and the second die 44, being first aligned, in a direction, substantially perpendicular to a floor upon which the die bonding apparatus is installed.

When applying a magnetic field, the uppermost die may be pressurized using the pressurizer 70 to dry the liquid L (S40, FIG. 8G). The pressurizer 70 maybe elastic rubber, and a head portion thereof may rubber.

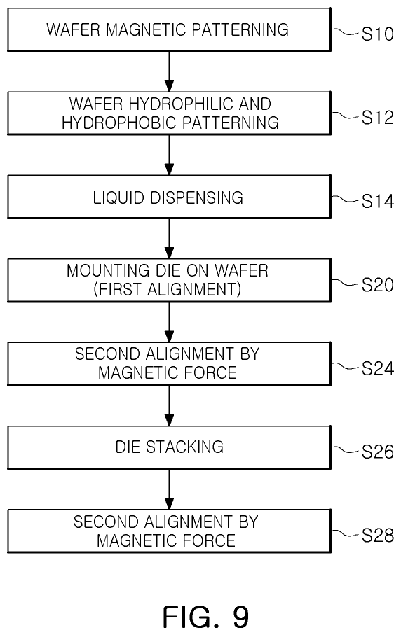

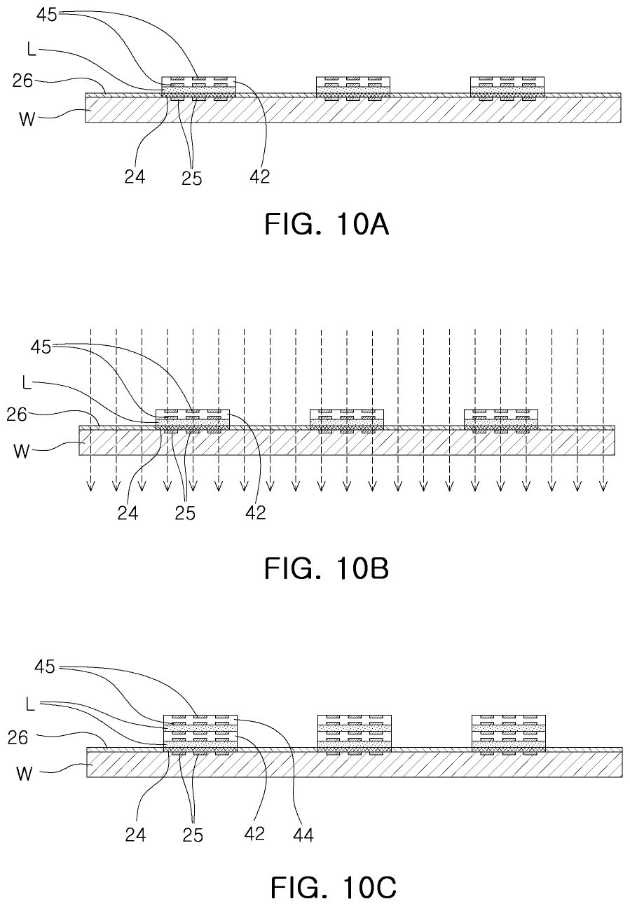

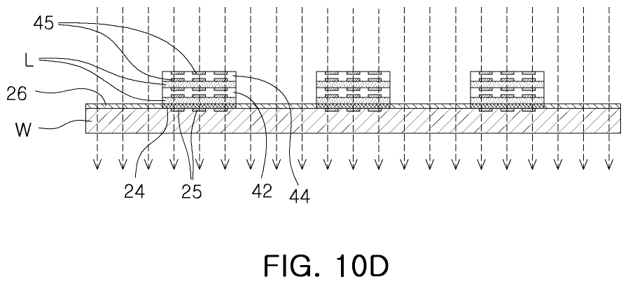

FIG. 9 is a flowchart of a die bonding method according to an embodiment of the present inventive concept, and FIGS. 10A to 10D are schematic diagrams illustrating the die bonding method of FIG. 9.

The die bonding method, according to another embodiment of the present inventive concept, will be described in detail with reference to FIGS. 9 and 10. In the present embodiment, the processes of FIGS. 7 and 8 and the processes of FIGS. 8A to 8D are the same.

Hereinafter, after the first die 42 is mounted on the wafer W, a magnetic field is provided to the magnet device 80. Here, the magnet device 80 is shown as integrated with the die transfer actuator 60.

In addition, the liquid dispenser 65 for generating capillary force may also be combined with the die transfer actuator 60 to form one module.

After first aligning the first die 42 on the wafer W, a second alignment may be performed first by applying a magnetic field (S24, FIGS. 10A and 10B).

Thereafter, the liquid L is dispensed on the upper surface 42U of the first die 42 on the secondly aligned wafer W, and then the second die 44 is mounted (S26, FIG. 10C). After the second die 44 is mounted, die-to-die bonding may be performed by applying a magnetic field for second alignment (S28, FIG. 10d).

Multitasking may be performed by repeating the processes of FIGS. 10C and 10D, and when second alignment is performed by providing magnetic force, drying may be performed by pressurizing by the pressurizer.

According to the die bonding apparatus and die bonding method using the same of the present inventive concept, ultra-precision wafer-to-die and die-to-die alignment is possible using capillary force and magnetic force, and not only may the equipment cost be reduced, but it also reduces bonding time and tact time.

While embodiments have been shown and described above, it will be apparent to those skilled in the art that modifications and variations could be made without departing from the scope of the present inventive concept.

What is claimed is:

1. A die bonding method using a die bonding device comprising a wafer shelf, a liquid dispenser, a die conveyer and a magnet device, comprising:
supplying a wafer, on which a hydrophilic pattern is formed, to a die seating portion, on which a first magnetic pattern is formed and a hydrophobic pattern is applied around the hydrophilic pattern, by means of the wafer shelf;
dispensing liquid to the die seating portion, by means of the liquid dispenser;
seating a first die, on which a second magnetic pattern connected to the first magnetic pattern is formed, on the wafer and first aligning the first die using capillary force of the liquid, by means of the die conveyor;
dispensing liquid onto an upper surface of the first die, by means of the liquid dispenser;
seating a second die on the upper surface of the first die and first aligning the second die with capillary force of the liquid on the upper surface of the first die, by means of the die conveyor; and
generating a magnetic field in the first magnetic pattern and the second magnetic pattern and secondly aligning the first magnetic pattern and the second magnetic pattern using magnetic force, by means of the magnet device.

2. The die bonding method of claim 1, wherein the liquid dispenser is integratedly combined with the die transfer actuator.

3. The die bonding method of claim 1, wherein, in the secondly aligning, the magnet device supplies a magnetic field to the first aligned wafer and the first die or the first die and the second die in a direction, substantially perpendicular to a floor upon which the die bonding apparatus is installed.

4. The die bonding method of claim 3, wherein the die bonding device further comprises a wafer transfer tool moving the first aligned wafer to the magnet device,
wherein the magnet device is a magnetic field generating chamber accommodating the first aligned wafer moved from the wafer transfer tool.

5. The die bonding method of claim 3, wherein the magnet device is integratedly combined with the die transfer actuator.

6. The die bonding method of claim 1, wherein the liquid generating capillary force includes water or a functional liquid reacting with a dielectric surface to form a silanol group (Si—OH).

7. The die bonding method of claim 1, wherein the first magnetic pattern or the second magnetic pattern is a soft magnetic material and includes Fe65-70Co30-35, permalloy (Ni60-80Fe40-20), soft-ferrite, and/or FePSi.

8. The die bonding method of claim 1, wherein the die bonding device further comprises a pressurizer pressurizing an uppermost die which is secondly aligned.

9. The die bonding method of claim 8, wherein the pressurizer includes a rubber head.

10. A die bonding method, comprising:
providing a wafer on which a hydrophilic pattern is applied to a die seating portion on which a first magnetic pattern is formed and a hydrophobic pattern is applied around the hydrophilic pattern;
dispensing liquid to the die seating portion;
seating a first die on which a second magnetic pattern connected to the first magnetic pattern is formed on the wafer and first aligning the first die using capillary force of the liquid;
dispensing liquid onto an upper surface of the first die;
seating a second die on the upper surface of the first die and first aligning the second die with capillary force of the liquid on the upper surface of the first die; and
generating a magnetic field in the first magnetic pattern and the second magnetic pattern and secondly aligning the first magnetic pattern and the second magnetic pattern using magnetic force.

11. The die bonding method of claim 10, wherein, in the secondly aligning, a magnetic field is supplied to the first aligned wafer and the first die or the first die and the second die in a direction, substantially perpendicular to a floor upon which the die bonding apparatus is installed.

12. The die bonding method of claim 10, wherein the liquid generating capillary force includes water or a functional liquid that reacts with a dielectric surface to form a silanol group (Si—OH).

13. The die bonding method of claim 10, wherein the first magnetic material or the second magnetic material is a soft magnetic material and includes Fe65-70Co30-35, permalloy (Ni60-80Fe40-20), soft-ferrite, and/or FePSi.

14. The die bonding method of claim 10, wherein, in the secondly aligning, the liquid between the wafer and the dies is dried.

15. The die bonding method of claim 14, wherein, when the liquid is dried, an upper surface of an uppermost die is pressurized.

16. A die bonding method, comprising:
providing a wafer on which a hydrophilic pattern is applied to a die seating portion on which a first magnetic pattern is formed and a hydrophobic pattern is applied around the hydrophilic pattern;
dispensing liquid to the die seating portion;
seating a first die on which a second magnetic pattern connected to the first magnetic pattern is formed on the wafer and first aligning the first die using capillary force of the liquid;
generating a magnetic field in the first magnetic pattern and the second magnetic pattern and secondly aligning the first magnetic pattern and the second magnetic pattern with magnetic force;
dispensing liquid onto an upper surface of the first die;
seating a second die on the upper surface of the first die and first aligning the second die with capillary force of the liquid on the upper surface of the first die; and
generating a magnetic field in the first die and the second die and secondly aligning the first die and the second die using magnetic force.

17. The die bonding method of claim 16, wherein, in the secondly aligning, a magnetic field is applied to the first aligned wafer and the first die or the first die and the second die in a direction, substantially perpendicular to a floor upon which the die bonding apparatus is installed.

18. The die bonding method of claim 16, wherein the liquid generating capillary force includes water or a functional liquid reacting with a dielectric surface to form a silanol group (Si—OH).

19. The die bonding method of claim 16, wherein the first magnetic material or the second magnetic material is a soft magnetic material and includes Fe65-70Co30-35, permalloy (Ni60-80Fe40-20), soft-ferrite, and/or FePSi.

20. The die bonding method of claim 16, wherein, in the secondly aligning, the liquid between the wafer and the dies is dried and an upper surface of an uppermost die is pressurized.
